(19) United States
(12) Patent Application Publication
(10) Pub. No.: US 2012/0248271 A1
(43) Pub. Date: Oct. 4, 2012

(54) Panel Lock Solar Clamp

(75) Inventor: Chad K. Zeilenga, Crete, IL (US)

(73) Assignee: ALLIED TUBE & CONDUIT CORPORATION, Harvey, IL (US)

(21) Appl. No.: 13/432,308

(22) Filed: Mar. 28, 2012

Related U.S. Application Data
(60) Provisional application No. 61/470,603, filed on Apr. 1, 2011.

(51) Int. Cl. H01L 23/12

(52) U.S. Cl. 248/231.41

(57) ABSTRACT

A clamp is disclosed for attaching a solar panel to a grid system. The clamp includes an upper end clamp, a clamp plate, a channel nut; and a fastener connecting the clamp, the clamp plate and the nut. A head of the fastener engages the upper end clamp and a threaded end of the fastener engages a hole in the channel nut so that rotation of the fastener fixes the clamp to a structural member. Rotation of the fastener also fixes a solar panel to the structural member. The upper end clamp has a side surface, and the clamp plate has a side surface. The side surfaces are in the same plane to enable them both to engage a side surface of the solar panel. The upper end clamp includes a protruding lip for engaging a top surface of a solar panel. Other embodiments are disclosed and claimed.

### CROSS-REFERENCE TO RELATED APPLICATIONS

This is a non-provisional of pending U.S. provisional patent application Ser. No. 61/470,603, filed Apr. 1, 2011, titled Panel Lock Solar Clamp, the entirety of which provisional application is incorporated by reference herein.

### BACKGROUND OF THE INVENTION

1. Field of the Invention

Embodiments of the invention generally relate to the field of mounting clamps, and more particularly to the field of mounting clamps for use in securing solar panels in various mounting applications.

2. Discussion of Related Art

Solar panels are typically used to convert solar energy to electrical power. In some cases, these solar panels are used to generate hot water. These panels have been utilized in these applications for many years. A typical solar panel installation is comprised of a mounted grid system employing one of many various types of structural products including strut, structural steel tubing, I-beam, steel channel, angle iron, wood and other structural shapes. The grid may be anchored to structural elements of the building or it may be mounted to the roof surface or mounted to the ground in ground mount applications. The individual solar panels are then connected to the grid to hold the panels at a desired orientation.

With recent emphasis placed upon alternative energy sources, there is a need for a convenient clamp for use in connecting solar panels to such grid structures. The clamp should enable quick and easy attachment of solar panels to grids, and should also be adaptable to use with various panel designs and product alternatives.

### SUMMARY OF THE INVENTION

A solar panel clamp is disclosed. The clamp includes an upper end clamp, a clamp plate, a channel nut; and a fastener connecting the upper end clamp, the clamp plate and the channel nut. A head of the fastener engages a top surface of the upper end clamp and a threaded end of the fastener engages a threaded hole in the channel nut so that rotation of the fastener in a first direction moves the channel nut toward the clamp plate to fix the solar panel clamp to a structural member disposed therebetween. Rotation of the fastener in the first direction also moves the upper end clamp toward the clamp plate to fix a solar panel to the structural member.

The upper end clamp has a side surface, and the clamp plate has a side surface. The side surfaces may be in the same plane to engage a side surface of the solar panel. The upper end clamp may include a protruding lip for engaging a top surface of a solar panel. The structural member may be a channel member, and the channel nut may include a pair of recesses for receiving corresponding channel edges of the channel member. The clamp plate may include first and second legs configured to lock over top portions of the channel member when the fastener is rotated in the first direction.

A solar panel clamp is disclosed, comprising an upper end clamp, a clamp plate, a channel nut, and a fastener connecting the upper end clamp, the clamp plate and the channel nut. A head of the fastener may engage a top surface of the upper end clamp and a threaded end of the fastener may engage a threaded hole in the channel nut so that rotation of the fastener in a first direction moves the channel nut toward the clamp plate to fix the solar panel clamp to a structural member disposed therebetween.

A solar panel clamp is disclosed, comprising an upper end clamp, a clamp plate, a channel nut, and a fastener connecting the upper end clamp, the clamp plate and the channel nut. A first end of the fastener may engage the upper end clamp and a second end of the fastener engages the channel nut so that actuating the fastener moves the channel nut toward the clamp plate to fix the solar panel clamp to a structural member disposed therebetween. The actuation of the fastener may also move the upper end clamp toward the clamp plate to fix a solar panel to the structural member.

### BRIEF DESCRIPTION OF THE DRAWINGS

The accompanying drawings illustrate preferred embodiments of the disclosed device so far devised for the practical application of the principles thereof, and in which:

FIG. 1 is an isometric view of the disclosed clamp;

FIG. 2 is a side view of the clamp of FIG. 1;

FIG. 3 is an end view of the clamp of FIG. 1;

FIG. 4 is an isometric view of the clamp of FIG. 1 fixed to an exemplary grid element;

FIG. 5 is an end view of the clamp of FIG. 1 fixed to an exemplary grid element;

FIG. 6 is an isometric view of a portion of the clamp of FIG. 1 associated with an exemplary grid element;

FIG. 7 is an isometric view showing a plurality of clamps according to FIG. 1 used to fix a pair of solar panels to an exemplary grid system;

FIG. 8 is a detail view showing the clamp of FIG. 1 engaging a solar panel and a grid element;

FIG. 9 is a side view of the arrangement of FIG. 8; and

FIG. 10 is an alternative side view of the arrangement of FIG. 8 showing the solar panel and grid in a tilted orientation.

### DESCRIPTION OF EMBODIMENTS

A clamp design is disclosed for use in securing solar panels to grid systems. Due to its strength-efficient design, the disclosed clamp may be formed in a manner as to provide high strength to offset in-situ forces such as panel weight, wind lift and snow loads. The disclosed clamp design includes features that enable it to be quickly and securely installed to fix one or more solar panel frames to a supportive grid system.

As will be described in greater detail, the disclosed clamp provides both a clamping force and a positive stop for the solar panel frame. The disclosed clamp can also accommodate a variety of solar panel heights, while limiting the moment force acting on the bolt securing the assembly. The clamp can be used with any type of grid structure and is not limited to a strut type system or a specific type of solar panel.

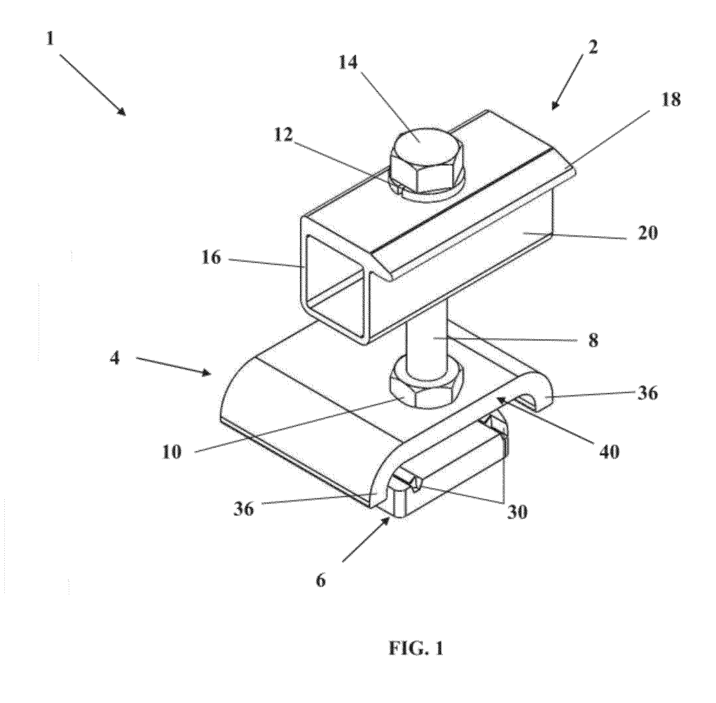

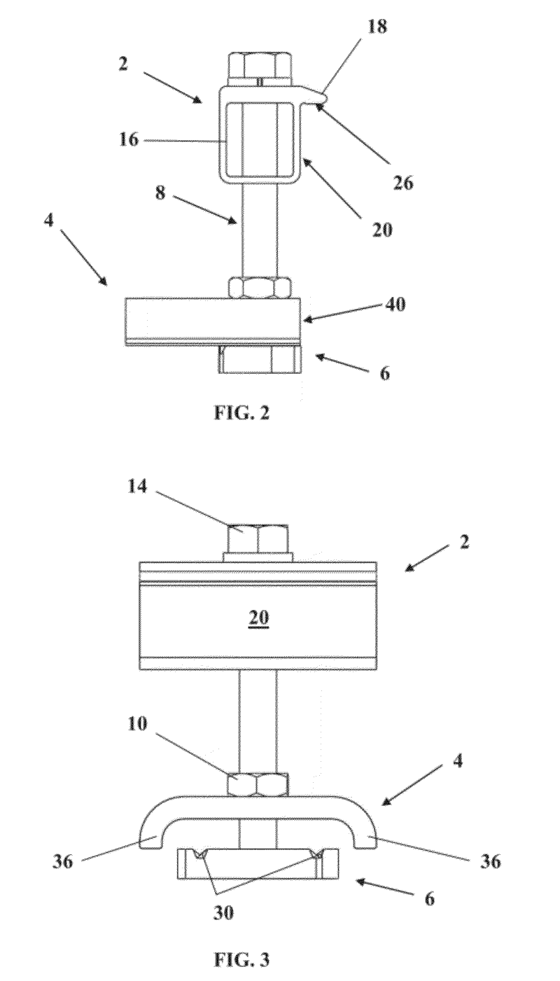

Referring to FIGS. 1-3, the clamp 1 may include an upper end clamp 2, a clamp plate 4, a channel nut 6 and a fastener 8 for connecting the upper end clamp 2 to the clamp plate 4. In one embodiment the fastener 8 is a bolt. A nut 10 may be disposed on the fastener 8 adjacent to the clamp plate 4 to fix the fastener axially with respect to the clamp plate 4. A lock washer 12 may be disposed between the head 14 of the fastener 8 and the upper end clamp 2.

The upper end clamp 2 may include a body portion 16 and a lip portion 18. The body portion 16 may include a side surface 20 for engaging a corresponding side surface 22 of a solar panel 24 (see FIG. 9). The lip portion 18 may have a panel engaging surface 26 oriented substantially perpendicular to the side surface 20 of the body portion 16 so that the two surfaces 20, 26 cradle corresponding side and upper surfaces 22, 28 of a solar panel 24.

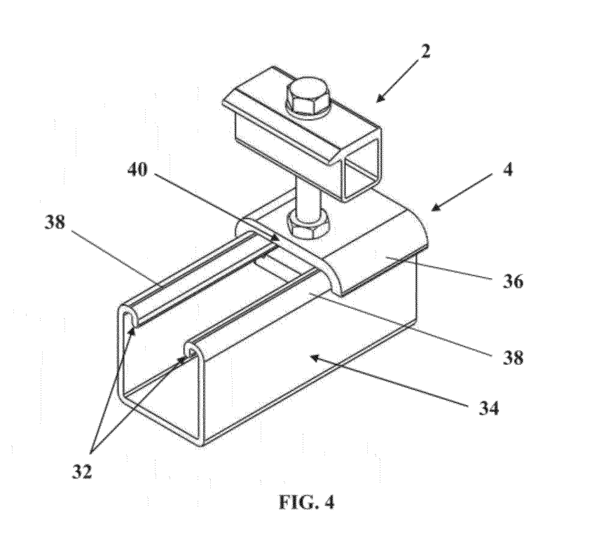

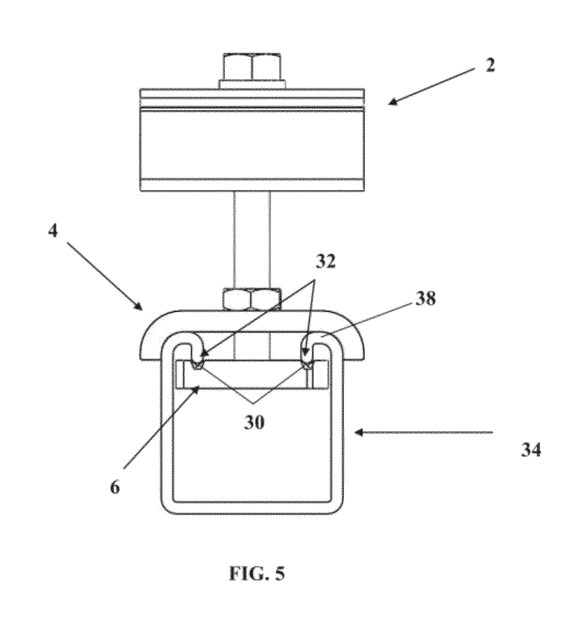

The interaction between the channel nut 6 and the clamp plate 4 enables the clamp 1 to be locked to an associated grid member. Thus, as can be seen in FIGS. 1 and 3, the channel nut 6 may include a pair of recesses 30 configured to engage corresponding channel edges 32 of a channel member 34 (see FIGS. 4 and 5). In a corresponding fashion, the clamp plate 4 may have first and second legs 36 configured to overlie, and wrap around, the top portions 38 of the channel member 34. As will be appreciated, this overlapping arrangement provides for easy centering of the clamp 1 on the channel member 34. In one embodiment, the first and second legs 36 are curved to match a corresponding curvature of the top portions 38 of the channel member. This arrangement also serves to lock the clamp 1 laterally to the channel member 34 when the device is tightened.

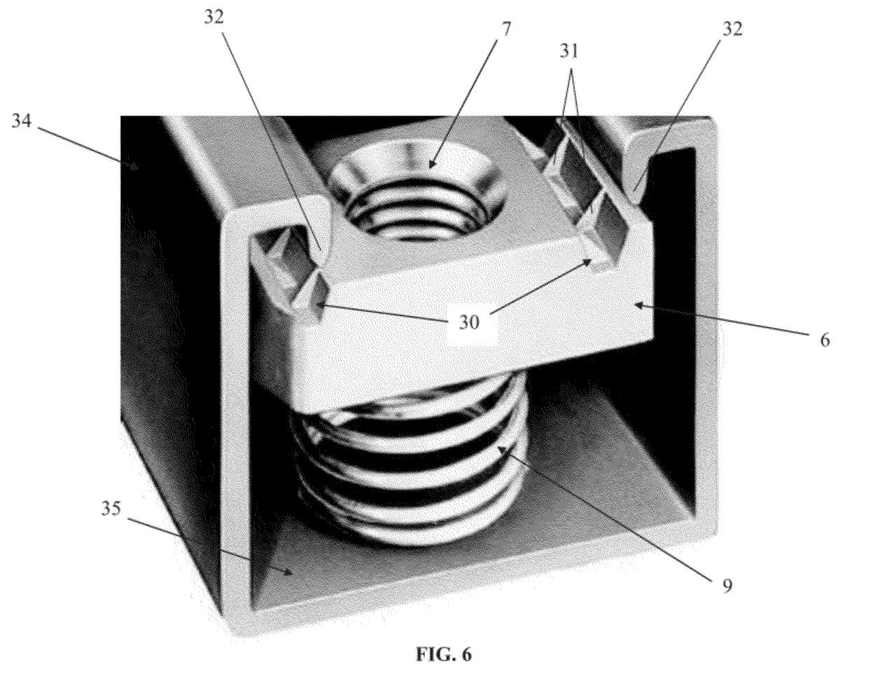

Tightening of the channel nut is achieved by rotation of the fastener 8. Specifically, the channel nut 6 has a threaded hole 7 (see FIG. 6) that receives a threaded end of the fastener 8 so that rotation of the fastener in a first direction causes the channel nut 6 to move toward the clamp plate 4. This causes the channel edges 32 of the channel member 34 to lock within the recesses 30 of the channel nut 6, and causes the first and second legs 36 of the clamp plate 4 to lock over the top portions 38 of the channel member. In this way, the clamp 1 is firmly fixed to the channel member 34. The disclosed arrangement also acts to tie the channel sides together in a “box” configuration for added strength.

FIGS. 4 and 5 show the inter-engagement of the clamp 1 with the channel member 34. Referring to FIG. 6, a spring 9 can be provided between the channel nut 6 and a bottom surface 35 of the channel member 34 to enable easy assembly of the clamp 1 at a desired location along the channel member 34. The spring 9 biases the channel nut 6 into engagement with the channel edges 32 of the channel member 34, provisionally fixing the clamp 1 to the channel member 34. This arrangement facilitates precision placement of the clamp 1 at any location along the channel length, and holds the channel nut 6 in position while the connection is completed.

To provide enhanced gripping and retention of the channel member 34, one or more surface features such as serrations, ridges or teeth 31 can be disposed within the recesses 30 of the channel nut 6. When the channel nut 6 is tightened during installation, the surface features bite into the channel edges 32 to prevent movement of the clamp 1 along the length of the channel member 34.

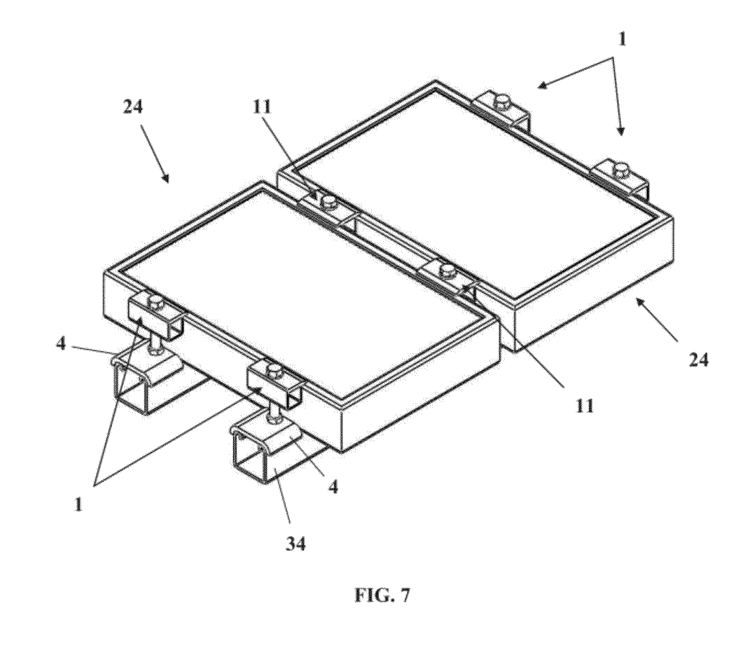

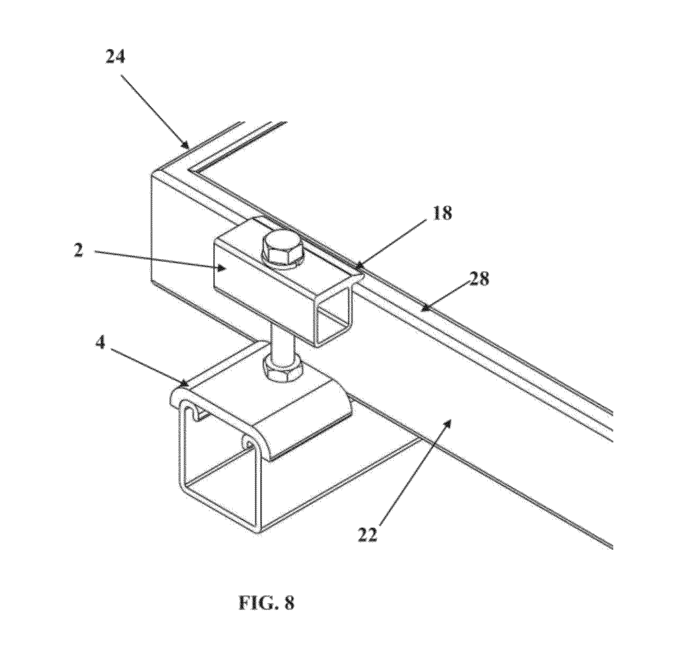

FIG. 7 shows a plurality of clamps 1 fixing a pair of solar panels 24 to a pair of channel members 34. As can be seen, the clamp plates 4 (and channel nuts 6) lock the clamps 1 to the channel members 34, while the upper end clamps 2 lock the clamps 1 to the solar panels 24 and press the solar panels 24 into locking engagement with the channel members 34. In the illustrated embodiment, a plurality of clamps 1 are used to fix the solar panels 24 to a pair of channel members 34. It will be appreciated that this arrangement is exemplary, and more (or fewer) channel members 34, and more (or fewer) clamps 1, can be used to engage and support a solar panel 24, depending upon particular design considerations.

FIG. 7 also shows the use of mid-clamps 11 between the adjacent solar panels 24. These mid-clamps may include a pair of oppositely disposed lips 18, to enable the mid-clamps 11 to engage a pair of adjacent solar panels 24. In one embodiment, the mid-clamps 11 do not employ a clamp plate. Instead, the fastener simply connects the upper end clamp to the channel nut to fix the solar panel to the channel member.

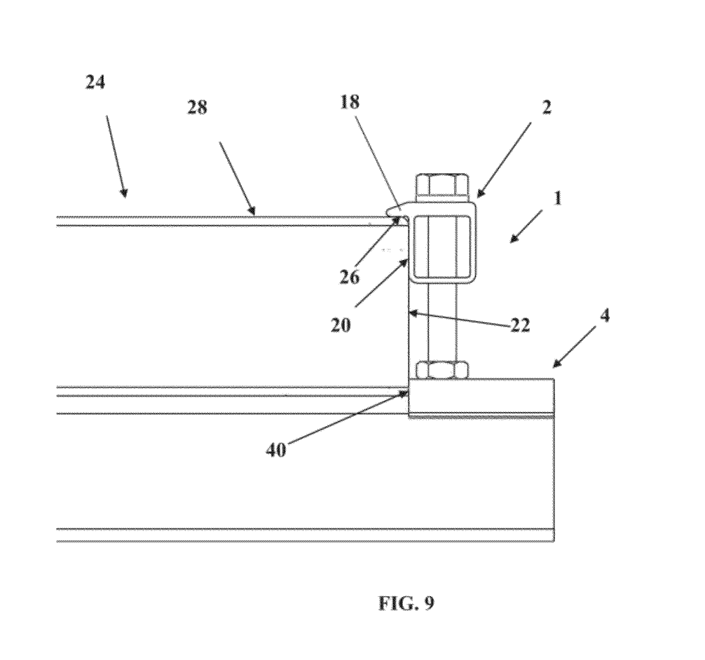

As can be seen in FIG. 7, the lips 18 and side surfaces 20 of the upper end clamps 2 engage the upper end of the upper and side surfaces 28, 22 of the solar panels 24. What should be noted in this arrangement is that a side surface 40 of each of the clamp plates 4 engages a lower end of the side surface 22 of each of the solar panels 24. This provides a two-point contact arrangement (i.e., the side surface 20 of the upper end clamp 2, and the side surface 40 of the clamp plate 4) that is more clearly shown in FIGS. 8-10.

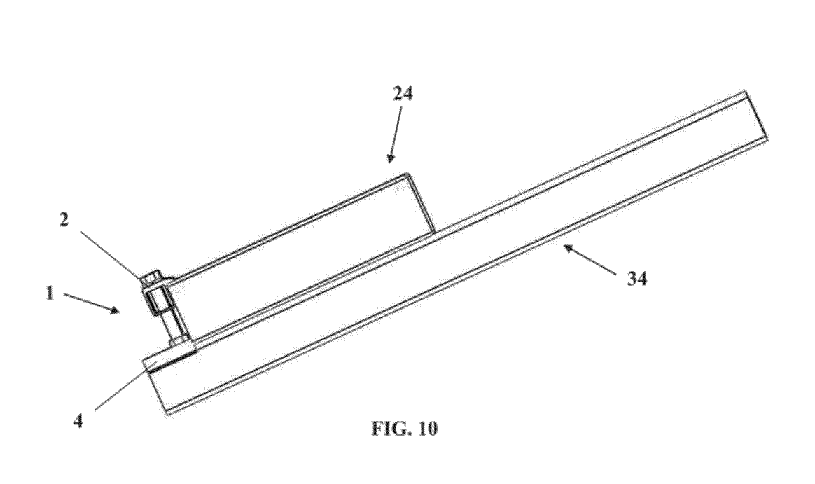

As can be seen best in FIGS. 9 and 10, the side surface 40 of the clamp plate 4 lies in the same plane as the side surfaces 20 of the upper end clamp 2. It will be appreciated that providing an additional engagement point (at the bottom of the panel, via the sides 40 of the clamp plates 4), eliminates the high moments that would otherwise be applied to the upper end clamps 2 due to the weight of the solar panels 24 and wind and snow loads. This two-point support arrangement is particularly advantageous where the solar panels 24 are mounted in a tilted (as opposed to flat) arrangement, commonly occurs. FIG. 10 shows such a tilted arrangement of a solar panel 24.

Thus arranged, the clamp 1 can be fit to a grid system (e.g., channel member 34) and engaged with a solar panel 24 so that the clamp plate 4 and the upper end clamp 2 engages a side surface 22 of the panel and so that the lip 18 overlies the upper surface 28 of the panel. Tightening the fastener 8 causes the channel nut 6 to be drawn toward the clamp plate 4, thus engaging the channel member 34. At the same time, the upper end clamp 2 is drawn down toward the clamp plate 4, thus pressing the solar panel 24 into engagement with a top surface of the channel member 34.

All, or portions, of the disclosed clamp 1 may be formed from aluminum, steel, fiberglass, reinforced polymers, etc., depending upon the needs and restrictions of the project. In one embodiment, the upper clamp 2 and the clamp plate 4 are made from extruded aluminum.

The disclosed clamp can be provided in multiple manners, dependent upon location of the project, relationships with the solar panel manufacturer, installation contractor or end user. The clamp can be provided individually as a component to be integrated into a larger design. Further, the clamp can be provided to solar panel manufacturers as a preferred method of attachment for their solar panels. It could also be provided as a part of a system approach including materials to fabricate and assemble an associated grid. Further, the clamp can be provided as a part of a total installation contract involving all or part of the structural aspects of a particular project.

While the clamp has been disclosed with reference to certain embodiments, numerous modifications, alterations and changes to the described embodiments are possible without departing from the spirit and scope of the invention, as defined in the appended claims. Accordingly, it is intended that the present invention not be limited to the described embodiments, but that it has the full scope defined by the language of the following claims, and equivalents thereof.

What is claimed is:

1. A solar panel clamp, comprising:
an upper end clamp, a clamp plate, a channel nut; and
a fastener connecting the upper end clamp, the clamp plate and the channel nut;
wherein a head of the fastener engages a top surface of the upper end clamp and a threaded end of the fastener engages a threaded hole in the channel nut so that rotation of the fastener in a first direction moves the channel nut toward the clamp plate to fix the solar panel clamp to a structural member disposed therebetween; and
wherein said rotation of the fastener in said first direction also moves the upper end clamp toward the clamp plate to fix a solar panel to the structural member.

2. The solar panel clamp of claim 1, wherein the upper end clamp includes a side surface and the clamp plate includes a side surface, the side surfaces oriented in the same plane to engage a side surface of the solar panel.

3. The solar panel clamp of claim 1, wherein the upper end clamp includes a protruding lip for engaging a top surface of a solar panel.

4. The solar panel clamp of claim 1, wherein the structural member is a channel member, and the channel nut includes a pair of recesses for receiving corresponding channel edges of the channel member.

5. The solar panel clamp of claim 4, wherein the clamp plate includes first and second legs configured to lock over top portions of the channel member when the fastener is rotated in the first direction.

6. The solar panel clamp of claim 1, wherein the upper end clamp includes a first protruding lip for engaging a top surface of the solar panel, and a second protruding lip for engaging a top surface of an adjacent solar panel.

7. A solar panel clamp, comprising:
an upper end clamp, a clamp plate, a channel nut; and
a fastener connecting the upper end clamp, the clamp plate and the channel nut;
wherein a head of the fastener engages a top surface of the upper end clamp and a threaded end of the fastener engages a threaded hole in the channel nut so that rotation of the fastener in a first direction moves the channel nut toward the clamp plate to fix the solar panel clamp to a structural member disposed therebetween.

8. The solar panel clamp of claim 7, wherein the upper end clamp includes a side surface and the clamp plate includes a side surface, the side surfaces oriented in the same plane to engage a side surface of the solar panel.

9. The solar panel clamp of claim 7, wherein the upper end clamp includes a protruding lip for engaging a top surface of a solar panel.

10. The solar panel clamp of claim 7, wherein the structural member is a channel member, and the channel nut includes a pair of recesses for receiving corresponding channel edges of the channel member.

11. The solar panel clamp of claim 10, wherein the clamp plate includes first and second legs configured to lock over top portions of the channel member when the fastener is rotated in the first direction.

12. The solar panel clamp of claim 7, wherein said rotation of the fastener in said first direction also moves the upper end clamp toward the clamp plate to fix a solar panel to the structural member.

13. A solar panel clamp, comprising:
an upper end clamp, a clamp plate, a channel nut; and
a fastener connecting the upper end clamp, the clamp plate and the channel nut;
wherein a first end of the fastener engages the upper end clamp and a second end of the fastener engages the channel nut so that actuating the fastener moves the channel nut toward the clamp plate to fix the solar panel clamp to a structural member disposed therebetween; and
wherein said actuation of the fastener also moves the upper end clamp toward the clamp plate to fix a solar panel to the structural member.

14. The solar panel clamp of claim 13, wherein the upper end clamp includes a side surface and the clamp plate includes a side surface, the side surfaces oriented in the same plane to engage a side surface of the solar panel.

15. The solar panel clamp of claim 13, wherein the upper end clamp includes a protruding lip for engaging a top surface of a solar panel.

16. The solar panel clamp of claim 13, wherein the structural member is a channel member, and the channel nut includes a pair of recesses for receiving corresponding channel edges of the channel member.

17. The solar panel clamp of claim 16, wherein the clamp plate includes first and second legs configured to lock over top portions of the channel member when the fastener is rotated in the first direction.

18. The solar panel clamp of claim 13, wherein the upper end clamp includes a first protruding lip for engaging a top surface of the solar panel, and a second protruding lip for engaging a top surface of an adjacent solar panel.
